(19) United States
(12) Patent Application Publication
(10) Pub. No.: US 2011/0266143 A1
(43) Pub. Date: Nov. 3, 2011

(54) SPUTTERING SYSTEM

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/857,503

(22) Filed: Aug. 16, 2010

(30) Foreign Application Priority Data
Apr. 28, 2010 (TW) 99113584

(51) Int. Cl. C23C 14/34; C23C 14/35

(52) U.S. Cl. 204/298.07; 204/298.25; 204/298.16

(57) ABSTRACT

A sputtering system includes at least two treatment chambers, at least two antechambers, a gas withdrawal device, a placement device, a removal device, and a transport device. The antechambers and the treatment chambers are connected to each other alternatively to form a loop. Each of the treatment chambers includes arcing sources received therein. The arcing sources are configured for carrying target materials and ionizing the target materials by electronic arc. The gas withdrawal device is configured for vacuuming the treatment chambers and the antechambers. When working, the placement device places workpieces into the loop, the transport device transports the workpieces in the loop for undergoing continuously sputtering, the removal device removes the workpieces from the loop after the sputtering process is finished.

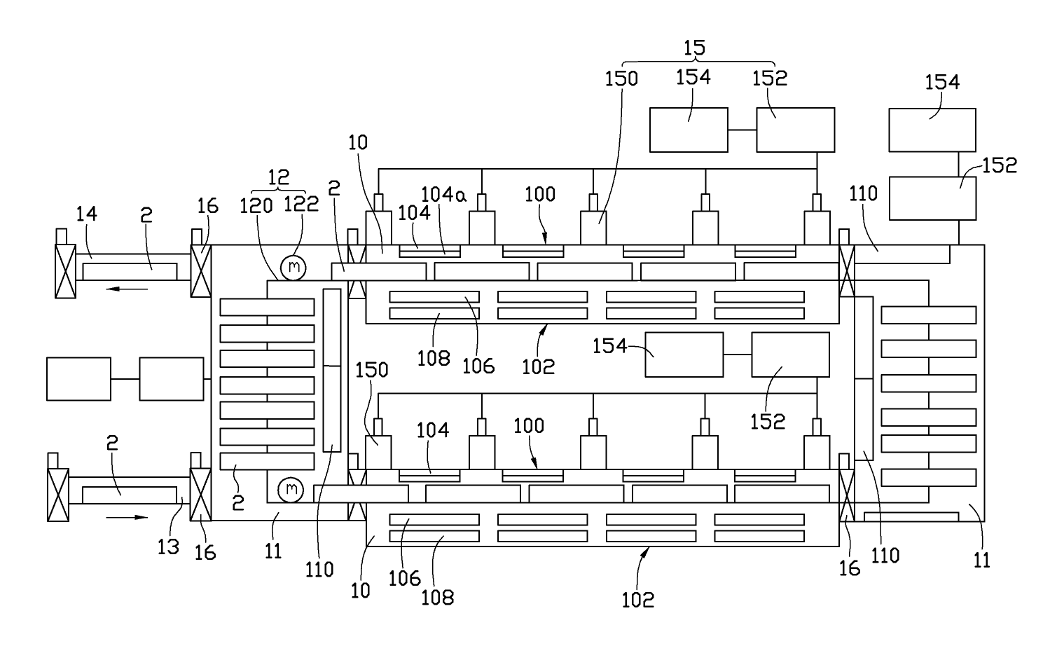

### BACKGROUND

1. Technical Field

The present disclosure relates to sputtering systems and, particularly, to a continuous sputtering system.

2. Description of Related Art

Sputtering methods are commonly used to coat films on surfaces of electronic devices, such as mobile phones, media players, etc. Yet, the sputtering method usually adopts only one treatment chamber for sputtering. One treatment chamber can only coat one kind of film on the electronic device, and therefore many chambers are required for when multiple layers of different kinds of film are needed.

Thus, what is needed is a sputtering system which overcomes the above mentioned shortcoming.

### BRIEF DESCRIPTION OF THE DRAWINGS

Many aspects of the embodiments can be better understood with reference to the following drawing. The components in the drawing are not necessarily drawn to scale, the emphasis instead being placed upon clearly illustrating the principles of the present disclosure.

The drawing is a schematic, structural diagram of the sputtering system according to an embodiment.

### DETAILED DESCRIPTION

Referring to the drawing, a sputtering system according to an embodiment is disclosed. The sputtering system is used for continuous sputtering on a plurality of workpieces 2. The sputtering system includes at least two treatment chambers 10, at least two antechambers 11, a transport device 12, a placement device 13, a removal device 14, gas withdrawal devices 15, and a plurality of valves 16.

The treatment chambers 10 are thin and long and have a generally rectangular shape, and each includes a first sidewall 100 and a second sidewall 102. The first sidewall 100 and the second sidewall 102 are parallel to each other and extend along a longitudinal direction of the treatment chamber. A plurality of arcing sources 104 are provided evenly spaced from each other in each treatment chamber 10 and are mounted on the corresponding first sidewalls 100. The arcing sources 104 carry target material 104a. Different target material 104a may be used in different treatment chambers 10. The gas withdrawal device 15 includes first vacuum pumps 150, second vacuum pumps 152, and third vacuum pumps 154. The first vacuum pumps 150 are mounted on the first sidewalls 100 on two ends of each arcing source 104. The first vacuum pumps 150 are connected to one of the second vacuum pumps 152 and one of the third vacuum pumps 154 in turn. Corresponding to each arcing source 104, a field coil 106 and a cooling device 108 are mounted on each second sidewall 102. The arcing sources 104 are configured for ionizing the target material 104a to produce target ions. The field coils 106 are configured for producing a magnetic field to guide the movement of the target ions. The cooling devices 108 are configured for cooling the treatment chambers 10 to ensure good sputtering quality.

In this embodiment, there are two treatment chambers 10 and two antechambers 11. The treatment chambers 10 and the antechambers 11 are alternately connected to each other by the valves 16 to form a loop. One of the antechambers 11 is further connected to the placement device 13 and the removal device 14 by the valves 16. The transport device 12 includes a carrying belt 120 and a driving motor 122. The carrying belt 120 extends through each treatment chamber 10 and antechamber 11 to form a loop. The carrying belt 120 carries the workpieces 2. The driving motor 122 drives the carrying belt 120 to move along a determined path to transport the workpieces 2 to the treatment chambers 10 and the antechambers 11 in turn.

Each of the antechambers 11 are connected to one of the second vacuum pump 152 and one of the third vacuum pump 153 sequentially. A heater 110 is mounted in each of the antechambers 11. The heater 110 is configured for heating up the workpieces 2 in the antechamber 11 to make the workpieces 2 being ready for undergoing sputtering in the treatment chamber 10.

When working, at first, the treatment chambers 10 and the antechambers 11 are vacuumed to a predetermined degree of vacuum by the first, second, and third vacuum pumps 150, 152, 156. Secondly, the workpieces 2 are put into one of the antechambers 11 by the placement device 13 and are carried by the carrying belt 120. The heater 110 heats up the workpieces 2 to a predetermined temperature. Thirdly, the transport device 12 transports the workpieces 2 into one of the treatment chambers 10 and the arcing sources 104 generate electric arcs to ionize the target materials 104a. The sputtered target ions, with an energy range of 10˜100 ev, are guided by the magnetic field produced by the corresponding field coil 106, and deposited on the surface of the workpieces 2 to form a film. Any ionized impurities, compared to the target ions, have an opposite polarity. Thus, ionized impurities will be blocked by the magnetic field and cannot reach the surface of the workpieces 2. In this way, a more pure film is obtained. Fourthly, the transport device 12 transports the workpieces 2 to another antechamber 11. The workpieces 2 are pretreated in the other antechamber 11, and then moved into another treatment chamber 10 for another film to be applied by sputtering. The workpieces 2 are treated in the antechambers 11 and the treatment chambers 10 alternately, till the sputtering process is finished. Finally, the workpieces 2 are removed by the removal device 14. Because the sputtering process can be done continuously, sputtering efficiency is greatly improved.

Moreover, it is to be understood that the disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A sputtering system comprising:
at least two treatment chambers, each of the treatment chambers comprising a plurality of arcing sources received therein, wherein the arcing sources are configured for carrying target materials and ionizing the target materials by electronic arc;
at least two antechambers, wherein the antechambers and the treatment chambers are connected to each other alternatively to form a loop;
a gas withdrawal device connected with the at least two treatment chambers and the at least two antechambers for vacuuming the at least two treatment chambers and the at least two antechambers;
a placement device and a removal device connected with one of the antechambers; and
a transport device; wherein
when working, the placement device places workpieces into the loop, the transport device transmits the workpieces in the loop for undergoing continuously sputtering, the removal device removes the workpieces from the loop after the sputtering process is finished.

2. The sputtering system of claim 1, wherein each of the at least two treatment chambers is rectangle shape and comprises a first sidewall and a second sidewall extending along a longitudinal direction of the treatment chamber and parallel to each other, and the arcing sources are mounted on the first sidewall and are provided evenly spaced from each other.

3. The sputtering system of claim 2, wherein each of the at least two treatment chambers further comprises field coils and cooling devices mounted on the second sidewall, the field coils and the cooling devices are correspond to the arcing sources one by one.

4. The sputtering system of claim 3, wherein the field coils are configured for producing magnetic field to guide the movement of the ionized target material.

5. The sputtering system of claim 2, wherein the gas withdrawal device comprising first vacuum pumps, second vacuum pumps, and third vacuum pumps, the first vacuum pumps are mounted on the first sidewall on two ends of each arcing source, and are connected to the second vacuum pumps and the third vacuum pumps in turn.

6. The sputtering system of claim 5, wherein each of the at least two antechambers are connected to one of the second vacuum pumps and one of the third vacuum pumps in turn.

7. The sputtering system of claim 1, further comprising a plurality of valves for connecting the at least two treatment chambers to the at least two antechambers, and connecting the placement device and the removal device to the one of the at least two antechambers.

8. The sputtering system of claim 1, wherein the transport device comprises a carrying belt extending through each of the at least two treatment chambers and each of the at least two antechambers and a driving motor for driving the carrying belt to move.
